(19) United States
(12) Patent Application Publication
(10) Pub. No.: US 2007/0228870 A1
(43) Pub. Date: Oct. 4, 2007

(54) Variable electrical circuit component

(76) Inventors: James Robert White, Pasadena, CA (US); Christopher John White, Pasadena, CA (US); Alexander Henry Slocum, Bow, NH (US)

Correspondence Address: James R. White, 1043 W. Del Mar Blvd., Pasadena, CA, 91106, US

(21) Appl. No.: 11/392,980

(22) Filed: Mar. 28, 2006

(51) Int. Cl. H01L 41/00

(52) U.S. Cl. 310/311

(57) ABSTRACT

A circuit component has an elastically deformable first structure, a second structure, and a support structure coupling the first and second structures, wherein the first structure can be variably deformed in response to a variable force, to provide either a variable capacitor or a variable tank circuit having a variable capacitor and an inductor. In one particular embodiment, a piezoelectric element is laminated to the surface of the first elastically deformable structure thereby providing the capability to deform the first structure. A method of making a circuit component includes forming an elastically deformable first structure, forming a second structure, and joining the first and second structures, to provide either a variable capacitor or a variable tank circuit having a variable capacitor and an inductor.

### CROSS REFERENCE TO RELATED APPLICATIONS

This application claims priority benefit of U.S. Provisional Application No. 60/______ filed Mar. 28, 2005.

### STATEMENT REGARDING FEDERALLY SPONSORED RESEARCH

Not Applicable.

### FIELD OF THE INVENTION

The present invention relates generally to electronic circuit components, and more particularly to variable capacitors and variably tunable tank circuits.

### BACKGROUND OF THE INVENTION

Many high frequency electronic systems benefit from the use of tunable passive elements such as capacitors and resonators. However, the performance of these tunable elements is typically limited by linearity, intermodulation products, loss and power handling. For example, a varactor diode is commonly used to provide a variable capacitance, however, a varactor often suffers from a limited tuning range (20%), high loss, poor intermodulation performance, and limited power handling. In other circuits, ferroelectric devices are used as tuning elements in place of varactor diodes. In yet other instances, microelectromechanical variable capacitors are used as tuning elements. However, all of these techniques suffer from poor linearity, which is an especially relevant constraint under high RF signal power conditions.

As is known, resonators with a variable resonant frequency can be constructed by assembling discrete variable capacitor and inductor elements. However, these resonant circuits typically suffer from a poor quality factor (Q), resulting in diminished narrowband performance such as increased insertion loss in the case of a filter. It is desirable to construct a resonant cavity wherein the unloaded Q is very high, thus allowing the implementation of a low insertion-loss narrowband tunable filter, or a low-phase noise tunable oscillator. Generally speaking, the quality factor is limited by the Q of the discrete elements that comprise a circuit. Losses in either an inductor element or a capacitor element will have the effect of reducing the overall system Q. A circuit design which minimizes the losses associated with these reactive elements, and minimizes the interconnection and parasitic losses is very desirable.

Given the breadth of applications for tunable passive elements such as capacitors, inductors and resonators, it would be desirable to overcome the aforesaid and other disadvantages, and to provide an electronic circuit component capable of providing a relatively wide tuning range and a relatively high Q, low intermodulation, high linearity and thermal stability.

A radio receiver is but one example of a wide variety of electronic devices that require the ability to tune to selected frequencies. Other examples include, but are not limited to, radio transmitters, power amplifiers, wireless telephones (voice and data), wireless modems, cable modems, radar systems, and scientific instrumentation, and all would make use of and be based upon the design and construction and operation disclosed in earlier U.S. Pat. No. 5,964,242 to Alexander H. Slocum, who is a co-applicant herein, and U.S. Pat. No. 6,914,785 to Alexander H. Slocum et al, the contents of both of which are herein incorporated by reference.

Many electronic devices require the ability to selectively tune one or more circuits to receive or transmit a selected one of a variety of radio signals, each associated with a relatively narrow band of frequencies about a corresponding center frequency. For example, a conventional radio receiver is designed to manually or automatically tune to enable reception of a selected radio signal from among many radio signals. By selectively tuning the radio receiver, any selected one of the many of radio signals can be received, down-converted to an audio signal, and presented to a user for listening. As is known, the many radio signals span a relatively wide frequency range, while each individual radio signal spans a relatively narrow frequency range, each having a different center frequency.

While the conventional radio receiver has selective tuning to tune near selected ones of the many radio signals, i.e. with selective “coarse” tuning, it should also be appreciated that the conventional radio receiver also has selective “fine” tuning, to tune within a narrower frequency range. Such fine tuning can variably move a tuned center frequency, first selected by the coarse tuning, to more accurately select a particular center frequency.

As is known, fixed electrical components typically suffer from component value drift with time and temperature, which can result in drift of a tuned circuit. With the selectable tuning described above, tuning drift can be overcome, and a tuning circuit, regardless of component drift, can still tune to a desired center frequency.

Some characteristics that are important in determining the effectiveness of an electronic tuning circuit include a total frequency span over which the selective tuning can tune, i.e., a coarse tuning range, an accuracy of the tuning, i.e. a fine tuning range and accuracy, and a selectivity of the tuning. The selectivity will be understood to be characterized by a quality or Q factor (or more simply “Q”), associated with the relative amplitude of a resonant peak and hence the minimum filter bandwidth capabilities.

Conventional electronic circuits are known which can provide selective coarse tuning over a wide range of frequencies, but with only a relatively low Q. For example, a phase locked loop (PLL), having a programmable divider, can provide selective tuning in a relatively wide range of frequencies. Conventional electronic circuits are also known which can provide selective tuning over only a small range of frequencies, but with a high Q on the order of several hundred. For example, a varactor diode is known to provide a variable capacitance, which can be used in conjunction with a fixed inductor and other electronic components in a resonant tank circuit to provide selective fine tuning. To this end, there also exist other passive components used in tank circuits (e.g. crystals, surface acoustic wave (SAW) devices, and bulk acoustic mechanical resonators), which provide relatively high Q (on the order of a thousand), low noise, and high stability necessary for highly-selective, low-loss fine tuning at radio frequencies (RF) and intermediate frequencies (IF). While a high Q is obtained with tank circuits, if used in a radio receiver without coarse tuning circuitry, the tank circuit could not tune over the full AM and FM frequency bands. Therefore, it should be understood that with conventional circuits a tradeoff must typically be made between total tuning frequency range and Q.

In order to achieve both a wide range of tuning and a high Q, many conventional electronic circuits incorporate both coarse tuning circuits, which conventionally have a wide tuning range but low Q, and fine tuning circuits, which conventionally have a low tuning range but a high Q. It will, however, be understood that the coarse tuning circuits and fine tuning circuits in combination represent a relatively complex and expensive electronic structure.

To replace the circuits described above, researchers have sought to develop micro electro-mechanical systems (MEMS) to provide on-chip voltage-tunable capacitors, low-loss inductors, and on-chip mechanical resonators. MEMS capacitors with a tuning range of approximately 6:1 at radio frequencies (RF) are known, but their robustness and Q have not met requirements. In addition, very low-loss inductors have yet to be demonstrated by other research groups.

It would, therefore, be desirable to overcome the aforesaid and other disadvantages, and to provide an electronic circuit component capable of providing a relatively wide tuning range and a relatively high Q.

### SUMMARY OF THE INVENTION

The present invention provides a tunable capacitor and/or a tunable tank circuit capable of tuning at relatively high signal frequencies, over a relatively wide range of frequencies, and with a relatively high Q factor, fabricated using electroforming, ceramic printed circuit board, and joining technology.

In accordance with the present invention, a circuit component has a first structure provided from an elastically deformable material. The circuit component also has a second structure with a surface proximate a surface of the first structure. The first and the second structures are coupled with a support structure which also acts as an elastic constraint to the first structure. The first structure can be elastically deformed, causing a portion of the surface of the first structure to move relative to the surface of the second structure, varying a gap. In one particular embodiment, the gap can range from microns to nanometers in size and is controllable with nanometer resolution. In one particular embodiment, the surface of the first structure and the surface of the second structure which are in proximity, each have a first conductive region, forming a first capacitor, the capacitance of which varies in proportion to the movement of the first structure relative to the second structure. In another embodiment, the surface of the first structure and the surface of the second structure which are in proximity, each also have at least one other conductive region, forming an inductor in parallel with the capacitor, and therefore, forming a tank circuit. In yet another embodiment, the circuit component includes a piezoelectric disk laminated or otherwise attached to the elastically deformable region of the first structure to form a piezoelectric bimorph actuator. In yet another embodiment, a flexible circuit element comprised of insulating and conducting layers may be disposed on the upper surface of the resonator or on the lower surface of the piezoelectric disc to electrically insulate the piezoelectric actuator from the elastically deformable metal structure, and to provide an electrical contact to the bottom surface of the piezoelectric disc.

To simplify the manufacturing process and reduce manufacturing costs, an inventive fabrication process for the production of the variable electrical circuit components of the present invention, incorporating metal electroforming techniques known for use in other applications was developed. The first elastically deformable structures of the inventive variable electrical circuit components may advantageously be fabricated by electroplating one or more thin layers of conductive material onto a mandrel having a complementary shape, polishing the surface of the electroplated layer until it exhibits a fine surface finish, dicing the electroplated layer into individual components and then releasing the electroplated layer from the mandrel using standard techniques, resulting in thin free-standing metal structures. This first metal structure may then be joined to a second structure having a conductive circuit topography patterned onto its surface. The first and second structures may be joined by means of an intervening conductive adhesive, or by direct joining techniques such as ultrasonic welding or thermocompression bonding. In one particular embodiment, a piezoelectric ceramic may be laminated onto the top surface of the first elastically deformable structure, providing a means of deforming the first structure in response to an applied electric field, and thus electronically controlling the capacitor gap. In another embodiment, the piezoelectric ceramic may be incorporated into the electroforming mandrel and is intimately joined to the first elastically deformable structure without intervening adhesives. This provides a significant advantage in reducing mechanical hysteresis associated with the deformation of the adhesive layer, and assembly complexity. By creating multiple such features on a larger mandrel, many such devices may be made in a single batch process.

With this particular arrangement of the present invention, a MEMS capacitor having a selectably variable capacitance value is provided. The capacitor can be provided as part of a variable tank circuit having a relatively wide tuning range and a relatively high Q.

In another arrangement, a stripline circuit pattern may be disposed upon the second substrate wafer forming the second structure of the variable electrical circuit component of the present invention, such that a variable input coupling capacitor, a variable tank capacitor and a variable output coupling capacitor may be formed between the second substrate and the top deformable conductive region of the first structure. In such an arrangement, the input and output capacitors have the effect of transforming the resonator impedance to the impedance of the input and output striplines respectively. Adjusting the size of the coupling capacitors allows the designer to adjust the electrical bandwidth of the resonator. In another embodiment, a circuit pattern may be disposed upon the second substrate wafer such that a fixed inductive input coupling structure and a fixed inductive output coupling structure are formed. Thus, either magnetic or capacitive coupling circuits can be formed to couple electromagnetic energy into and out of the variable tunable element.

With this particular arrangement, the method provides a variable capacitor and/or a variable tank circuit having a relatively wide tuning range and a relatively high Q.

### BRIEF DESCRIPTION OF THE DRAWINGS

The foregoing features of the invention, as well as the invention itself may be more fully understood from the following detailed description of the drawings, in which:

FIG. 1 is a cross-sectional schematic view through a version of the device showing the inductor cavity, the central capacitor and a piezoelectric element for tuning;

FIG. 2 is a cross-sectional schematic view of the resonator with a tuning voltage applied to the piezoelectric actuator.

FIG. 3 is an exploded view that shows the assembly of the cavity;

FIG. 4 is an isometric view of the system with a piezoelectric bimorph actuator;

FIG. 5 shows the dependence of the actuator displacement on the diaphragm dimensions;

FIG. 6 shows a cross-sectioned view of a device with principal dimensions labeled;

FIG. 7 shows a schematic plan view of the fixed ceramic substrate including coupling capacitor and tank capacitor regions with principal dimensions labeled;

FIG. 8 shows the lumped-parameter equivalent circuit for the device;

FIG. 9 shows the frequency response (S₂₁) of a typical two-port device tuned to resonate at 1.41 Ghz, 2.30 Ghz and 3.50 Ghz by varying the applied piezoelectric tuning voltage;

FIG. 10 shows the center frequency versus piezo tuning voltage;

FIG. 11 shows the resonant frequency vs center frequency of a typical device;

FIG. 12 shows the quality factor (Q) vs center frequency of a typical device;

FIG. 13 shows the insertion loss vs. center frequency of a typical device.

FIG. 14 shows a four-port tunable capacitor device;

FIG. 15 shows an equivalent circuit for the four-port tunable capacitor.

### DETAILED DESCRIPTION OF THE INVENTION

Before describing the circuit components of the present invention, mention is made as to the format of some of the figures. Those figures shown and described as cross-sectional figures are drawn without some hidden lines representing features behind the section region. Those lines behind the section region, if drawn, would add unnecessary complexity to the drawings and obscure the features which are described. In effect, the cross-sectional figures may be thought of as “slice” figures, representing a slice of an apparatus.

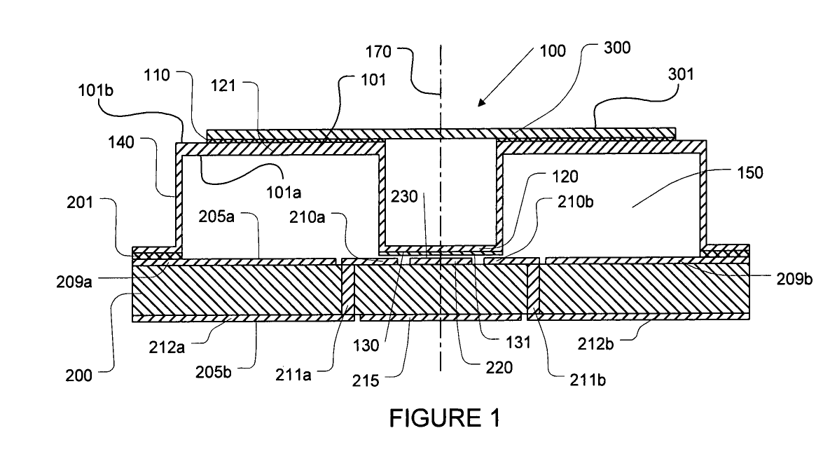

Referring now to FIG. 1, an exemplary circuit component 100, includes a first (or upper) structure 101, provided from an elastically deformable material, having a first surface 101a and a second surface 101b. In one particular embodiment, the circuit component 100 is symmetrical about the axis 170. In another embodiment, the circuit component 100 can be provided having circular symmetry about the axis 170, and thus the circuit component 100 is essentially round. In another embodiment, the structure could be shaped in the form of a polygon or other shape. The first structure 101 may be fabricated from a conductive material such as a conductive metal. The first structure 101 may have a thin layer of conductive adhesive 110 disposed upon the surface 101b, which bonds the thin piezoelectric disc 300 to the deformable material 121 creating a piezoelectric bending bimorph actuator. The second structure 200 has a top surface 205a and a bottom surface 205b. In some embodiments, a conductive layer disposed upon the top surface 205a may be patterned to form independent variable input and output coupling capacitors 210a and 210b, and a variable tank capacitor 220 between the surfaces 230 and 130. In one implementation, a dielectric layer 131, for example parylene-N, may be disposed upon the inner surface of the element 101, preventing conductive surfaces 230 and 130 from touching. The conductive regions 101a, 140 and 205a form the periphery of a single-turn toroidal inductor 150 that is electrically connected to the bottom plate 220 of the variable tank capacitor. Structure 101 may be anchored to surface 205a with thin film attachment means 201, such as an adhesive, or alternatively it may be laser welded or ultrasonically welded, eliminating the film 201.

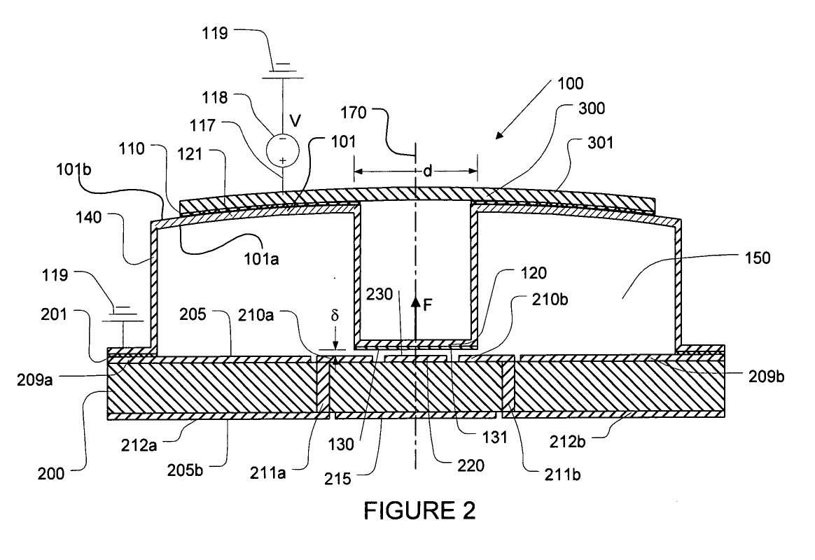

Referring now also to FIG. 2, an exemplary circuit component 100 includes a first (or upper) structure 101, provided from an elastically deformable material, having a first surface 101a and a second surface 101b. The first structure 101 has a central region 120, which in an alternative embodiment (not shown) may be thicker than the flexible diaphragm region 121. The upper circuit component 101 may be electrically connected to “ground,” 119, while the conductive surface 301 of the piezoelectric element 300 may be electrically coupled by a wire 117 connected to a high-voltage power supply 118 capable of adjusting the electric field across the piezoelectric disk. This piezoelectric bimorph structure, as is known in the art, creates an effective force F acting upon the central region 120, thereby varying the gap δ between surfaces 130 and 230 in the direction of axis 170. It should be noted that the sidewall 140 of the inductor cavity 150 also acts as an elastic fulcrum to support the outer edge of the flexible diaphragm 101 so the force F can produce reasonable capacitance changes. Sidewall 140 can be very short, even just a rim if the inductor cavity 150 is machined into the substrate 200, for example.

The exemplary circuit component 100 also includes a second (or lower) structure 200, having a first surface 205a and a second surface 205b. The conductive material disposed upon the first surface 205a of the lower structure 200 is structured to provide an input coupling capacitor plate 210a, a tank capacitor plate 220 and an output coupling capacitor plate 210b. Thus, three parallel-plate capacitors may be formed between the input plate 210a, the tank plate 220 and the output plate 210b and the movable top plate 120. Conductive vias 211a and 211b provide an electrical contact path to the second conductive layer 205b. Input and output striplines, 212a and 212b respectively, are used to couple electrical power into and out of the coupling capacitor plates 210a and 210b. A bottom conductive material is disposed upon the surface 205b and patterned to define input and output striplines 212a and 212b, respectively, and a ground plane 215. The tank capacitor plate 220 may preferably be electrically grounded. Additional ground vias (not shown) may couple the top ground plane regions 209a, 209b and 220 to the bottom ground plane 215, thereby decreasing any parasitic coupling between input and output striplines 212a and 212b respectively.

In one exemplary embodiment, the force F can be provided by piezoelectric element 300 coupled to the second surface 101b of the first structure 101. In such an embodiment, in response to a signal provided thereto, the piezoelectric element may provide a force upon the first structure 101 in the lever regions formed by the side structure 140. While the piezoelectric element 300 is shown, in other embodiments, an external piezoelectric stack or any suitable electrostatic or electromechanical actuator can be provided in place of, or in addition to, the piezoelectric element 300 to provide the force F upon the second surface 130.

In one particular embodiment, the first structure 101 may be made from metal, for example copper metal, using electroforming techniques, and the second structure 200 may be made from ceramic, such as for example, Aluminum Nitride, Aluminum Oxide, or Pyrex™ with conductive regions disposed and patterned thereupon using conventional circuit processing techniques that are widely known in the art. In another embodiment, the first structure 101 may be made from a metal alloy, for example “Alloy 42”, whose composition of Nickel and Iron may be adjusted such that the metal alloy has a coefficient of thermal expansion that is closely matched to the ceramic of the second structure 200. Furthermore, the inner surface 101a of the first structure 101 can have a thin layer (1-3 microns) of non-ferromagnetic material such as copper or gold disposed upon it to desirably reduce the level of third-order intermodulation at RF frequencies.

FIG. 2 shows the effective deflection force F, generated by the action of the exemplary piezo actuator 300 on the central region 120, causing separation of the first and second conductive layers 130, 230 respectively, forming a gap 6. It will be understood that the size of the gap δ is influenced by the magnitude of the force F and the stiffness of the structures 101 and 140. Therefore, the layers 130 and 230 form a variable capacitor having a capacitance that varies in proportion to the force F. As the force F increases, the gap δ tends to increase, therefore reducing the capacitance. Furthermore, the direction of the force F can be reversed by reversing the direction of the electric field applied across the piezoelectric actuator 300. In this case, the gap δ decreases in size, thereby increasing the capacitance. In addition, there can be an initial gap between conductive layers 130 and 230 due to bow and warp of the surfaces, or residual thermal stresses produced during component manufacturing.

As described above, in other embodiments, the force F can equally well be applied with another type of actuator in place of or in addition to the piezoelectric element 300. For example, in other embodiments, the force F can be applied with an external electro-mechanical actuator or piezoelectric stack actuator (not shown).

Because the gap δ of the circuit component 100 has a high aspect ratio, i.e., a major axis or a diameter d much greater than the gap 6, which can be precisely controlled, the circuit component 100 can form a capacitor having a relatively wide range of achievable capacitance values. A tuning ratio can be defined as the largest capacitance value which can be achieved divided by the smallest capacitance value which can be achieved, and the capacitor 100 is provided having a relatively high tuning ratio. In one particular embodiment, the tuning ratio may be 10, although values up to at least about 100 may be achieved. With addition of an integral inductor as described more fully below, a tunable LC resonator circuit, or LC tank circuit, may operate from, for example, UHF (Ultra-High Frequency) to SHF (Super-High Frequency) and may be capable of band selection over a wide frequency range. It should, however, be appreciated that the structures and techniques described herein may also be applied to frequency ranges which are lower than and higher than UHF and SHF.

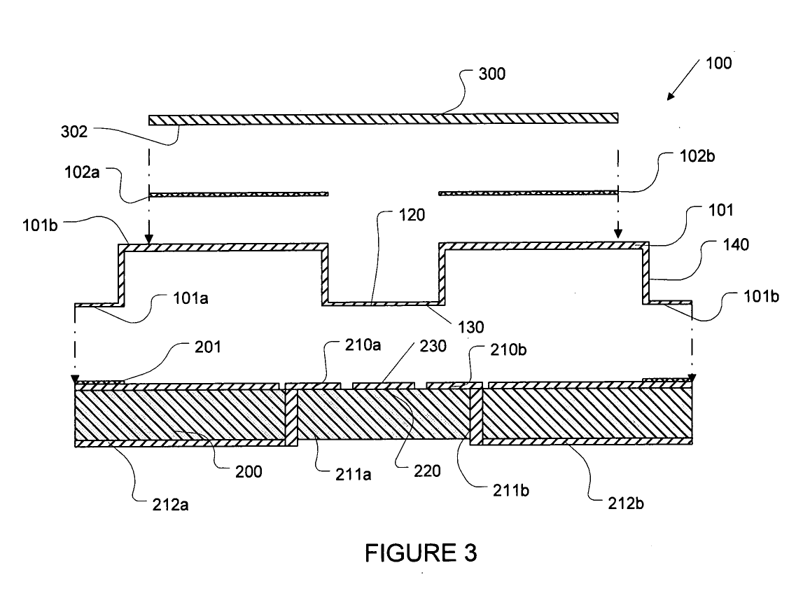

FIG. 3 shows a metal resonator cavity 101 which may be formed by advantageously adapting conventional electroforming techniques such as by electroplating one or more thin layers of conductive material onto a mandrel having a complementary shape, polishing the surface of the electroplated layer until it exhibits a fine surface finish, dicing the electroplated layer into individual components and then releasing the electroplated layer from the mandrel using standard techniques, resulting in the resonator cavity 101, or by other known means for producing a thin-walled conductive geometry. A ceramic circuit board 200 having patterned metal interconnections, for example 212a and 212b, and through-hole vias, for example 211a and 211b, may be fabricated by advantageously adapting conventional ceramic circuit-board techniques known in the art. A thin adhesive layer 201 may be applied around the periphery of the ceramic tile. Subsequently, the resonator cavity 101 may be pressed against the thin adhesive layer 201, and the adhesive may be allowed to cure, thereby electrically and mechanically joining resonator cavity 101 and the patterned ceramic circuit board 200. A second layer of conductive adhesive 102a and 102b may be disposed upon the top surface 101b of the resonator cavity 101, and a piezoelectric disk element 300 may be pressed against the adhesive layer. Care must be taken to avoid applying excess conductive adhesive, or the excess can squeeze out from the interface and short-circuit the top and bottom surfaces of the thin piezoelectric disk. In an alternate embodiment, the adhesive 102a and 102b may be a non-conductive adhesive, for example cyanoacrylate, thin enough to still allow electrical interconnections between asperities on the surface 302 of the piezoelectric disk and surface 101b of the electrical resonator.

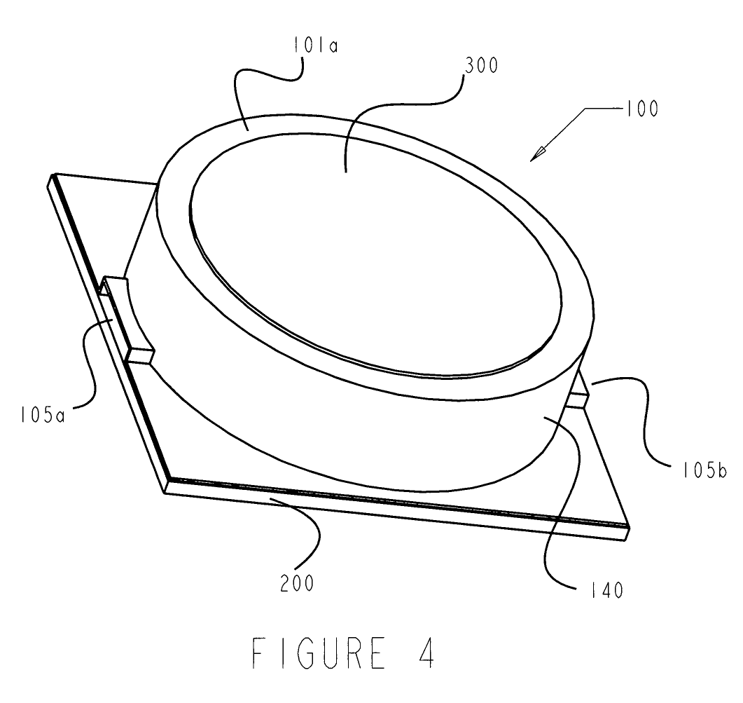

Referring now to FIG. 4, in which like elements from FIG. 1 are shown with like reference designations, an exemplary circuit component 100 having circular symmetry is shown in an isometric view. A piezoelectric disk 300 is bonded to the top surface 101a of the resonator 101. Rectangular coaxial feed-throughs 105a and 105b are formed in the side 140 of the resonator allowing for lateral electrical interconnections into the resonator cavity if desired. The resonator 101 may be bonded to the ceramic substrate 200 such as by using adhesive or welding means, as described previously.

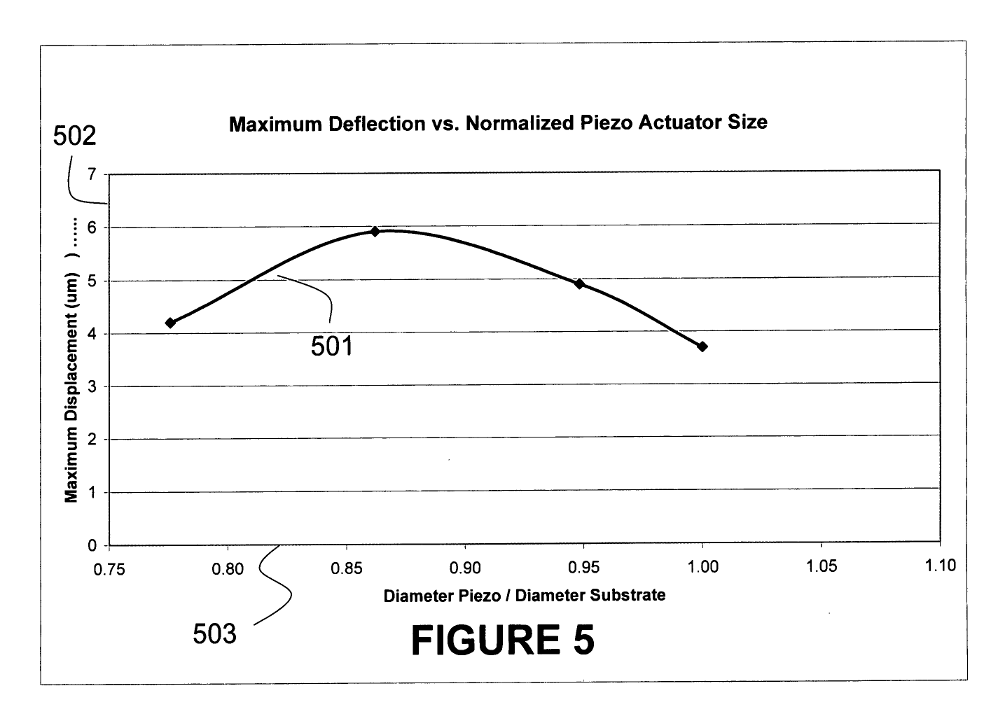

Referring now to FIG. 5, the maximum actuator displacement, for a given 3.5×10⁵ V/m electric field across an exemplary piezoelectric actuator, and for a piezo disk thickness of 100 microns, and a metal diaphragm thickness of 75 microns, is plotted as a function of the relative diameters of the piezoelectric disk and the metal diaphragm. The maximum displacement is 5.9 microns for an exemplary piezoelectric disk diameter of 10 mm and a metal diaphragm diameter of 11.6 mm.

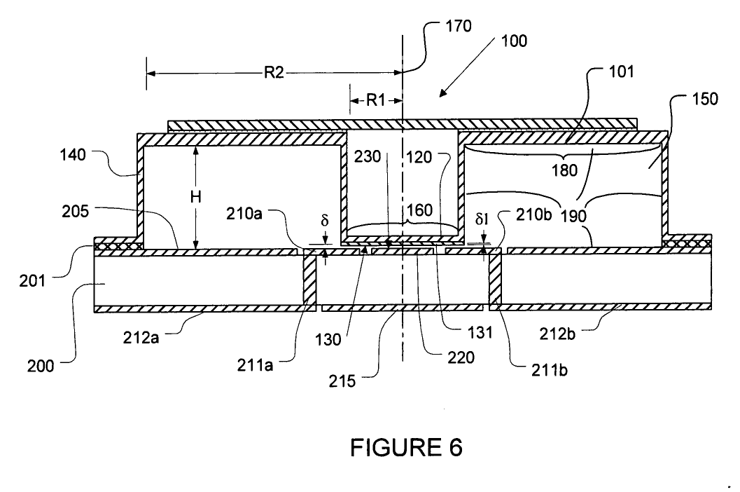

Referring now to FIG. 6, in which like elements from FIG. 1 are shown with like reference designations, an exemplary tunable tank circuit 100 includes a first structure 101 preferably made of highly conductive metal, and having a central axis 170. The tunable tank circuit 100 also includes a second structure 200 having a conductive region 205, and conductive regions 210a and 210b. The conductive region 205 may be joined to the structure 101 by a flexible conductive structure 140 such as by using conductive epoxy 201 or a direct joining technique. The conductive regions 160 and 220 form a variable capacitor having a capacitance related to the area and width of a variable gap 6, and the conductive regions 205, 140 and 180 form an inductor 190 having an inductance that is substantially fixed as determined by the dimension H as well as the dimensions of conductor 205. The conductive region 160 and 220, each have a radius R1, and the conductive regions 180 have inner and outer radii R1 and R2 respectively. The area of region 220 may be decreased by the coupling structures 210a and 210b. Region 220 may be electrically connected to region 205. An insulating layer 131 may be disposed on the conductive region 160, having a fixed thickness δ₁.

The electrical response characteristics of the circuit component 100 may be analyzed by first assuming that a current flows into the conductive region 160 and out the conductive region 220, by also assuming that current distributes evenly, forming a surface current K_{f} in the closed conductor 190, by also assuming that magnetic flux lines (not shown) are contained inside the effective toroid 150 formed by the conductive regions 190 and 180 respectively, and by assuming that an H field is zero directly outside of the closed conductor. A boundary condition, n×(H^{a}−H^{b})=K_{f}, may be used, where H^{a} is inside the toroid and H^{b} is outside. Therefore, in such case, the H field inside the toroid is H^{a}=K_{f}.

The surface current K_{f} is a function of the radius r is:

$${K}_{f} = H = \frac{I}{2 π r} , \qquad ( 1 )$$

The flux density is thus

$$B = {μ}_{o} H = \frac{{μ}_{o} I}{2 π r} . \qquad ( 2 )$$

To calculate inductance, the total flux in the toroid may be calculated. This is done by integrating the flux density across a cross-sectional area of the toroid. Dividing the flux-linkage by the current gives the inductance,

$$\begin{matrix}ϕ = λ = {\int }_{0}^{H} {\int }_{R 1}^{R 2} \frac{{μ}_{o} I}{2 π r} ⅆ r ⅆ z \\ & ( 3 ) \\ L = \frac{λ}{I} = \frac{{μ}_{o} H}{2 π} ln \frac{{R}_{2}}{{R}_{1}} & ( 4 )\end{matrix}$$

Capacitance between the conductive regions 160 and 220 respectively, derived by inspection, is written below, taking into account the effect of a higher permittivity, ∈₁, of the oxide layer 131 and the thickness δ₁ of the oxide layer 131:

$$C ( δ ) = \frac{{ɛ}_{1} {δ}_{1} + {ɛ}_{0} δ}{{( {δ}_{1} + δ )}^{2}} A . \qquad ( 5 )$$

The resistance of the toroid, i.e., effective resistance in series with the inductor formed by the conductive regions 190 and 180 respectively, is calculated below. A skin depth w_{Au} is a function of resonant frequency. The calculated resistance below does not take into account dielectric hysteresis, radiation, charge relaxation time constants, and leakage through first structure 101, all of which tend to reduce the Q of the tank circuit.

$$\begin{matrix}R = \frac{1}{2 π {σ}_{Au} {w}_{Au}} ( \frac{H}{{R}_{1}} + \frac{H}{{R}_{2}} + 2 ln \frac{{R}_{2}}{{R}_{1}} ) & ( 6 ) \\ {w}_{Au} = \sqrt{\frac{2}{ω {μ}_{o} {σ}_{Au}}} & ( 7 )\end{matrix}$$

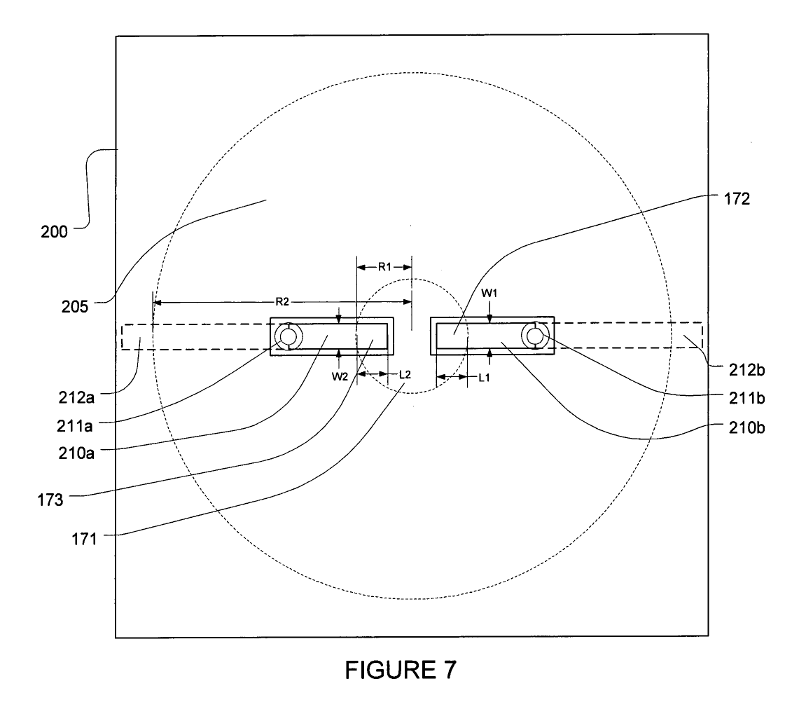

Referring now to FIG. 7, conductive regions 210a and 210b may be disposed on the fixed ceramic substrate 200, thereby forming structures that couple RF energy into an out of the resonant cavity. The capacitance of the coupling circuit corresponding to 210b may be represented by:

$$C ( δ ) = \frac{{ɛ}_{1} {δ}_{1} + {ɛ}_{0} δ}{{( {δ}_{1} + δ )}^{2}} {W}_{1} {L}_{1} \qquad ( 8 )$$

and the capacitance corresponding to the coupling circuit 210a may be represented by:

$$C ( δ ) = \frac{{ɛ}_{1} {δ}_{1} + {ɛ}_{0} δ}{{( {δ}_{1} + δ )}^{2}} {W}_{2} {L}_{2} . \qquad ( 9 )$$

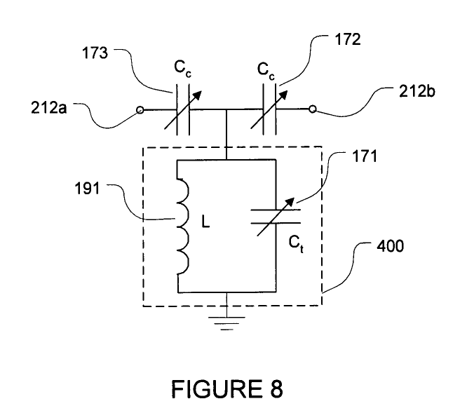

Referring now to FIG. 8, an equivalent lumped-parameter circuit is shown. Input stripline 212a couples energy into the resonant tank 400 through capacitor Cᵢ 173. Output stripline 212b couples energy out of the resonant tank 400 through capacitor Cₒ 172. Tank capacitor Cₜ 171 varies in concert with coupling capacitors Cᵢ 173 and Cₒ 172, thus the ratio of tank and coupling capacitors may be held constant even as the capacitor spacing is varied.

In one particular embodiment R1 is 2.5 mm, R2 is 5.8 mm, d is 3 mm, the thickness of the insulating layer 131 is 100 nm, the variable gap δ can be varied in a range between about 1 μm and 20 μm (although the desired range could be from about 100 um to 10 nm), the closed conductor 191 may comprised of gold having a skin depth of 1.61 μm, a calculated inductance of the toroid 150 is 505 pico-Henries (pH), a calculated equivalent series resistance of the toroid is 8.2 mΩ, a capacitance of the capacitor formed by the conductive regions 160, 170, respectively, varies between 173 pico-Farads (pF) and 8.69 pF as the variable gap is varied in the above range. The coupling capacitor regions are each 0.75 mm×0.5 mm, thus the coupling capacitance varies between 0.16 pF and 3.3 pF. The resonant frequency of resonant cavity varies between 534 Mhz and 2.38 GHz as the variable gap is varied in the above range, and the loaded Q varies between 26.7 and 198 as the variable gap is varied in the above range, and the 3 dB bandwidth of the resonance, given 50-Ohm input and output coupling, is between 20 Mhz and 12 Mhz as the variable gap is varied in the above range. However, in other embodiments, other dimensions and characteristics can be selected in order to provide a circuit component having another capacitance range, another inductance, another bandwidth, another range of resonant frequencies, and another range of Qs.

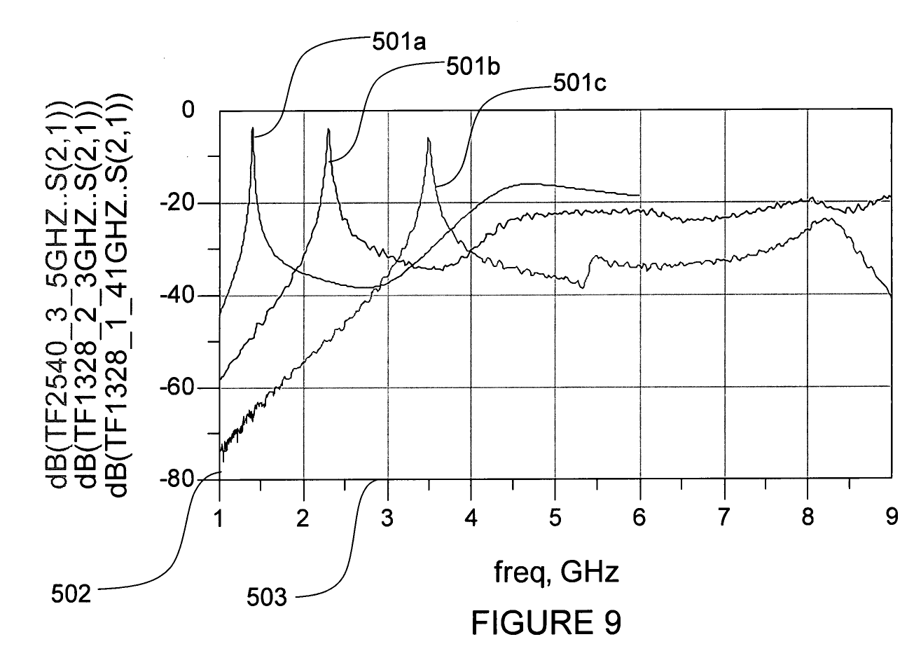

Referring now to FIG. 9, curves 501a, 501b and 501c represent S₂₁, i.e. the power transmitted between the input and output ports of the tunable resonator for a range of applied tuning voltages. The transmitted power S₂₁ (in dB) is shown along axis 502. The frequency, in Ghz, is shown on axis 503. FIG. 9 shows that the insertion loss of a two-port one-pole resonator device is between −3.0 dB at 1.41 Ghz and −2.1 dB at 3.50 Ghz, for a fixed resonator bandwidth of 25 Mhz.

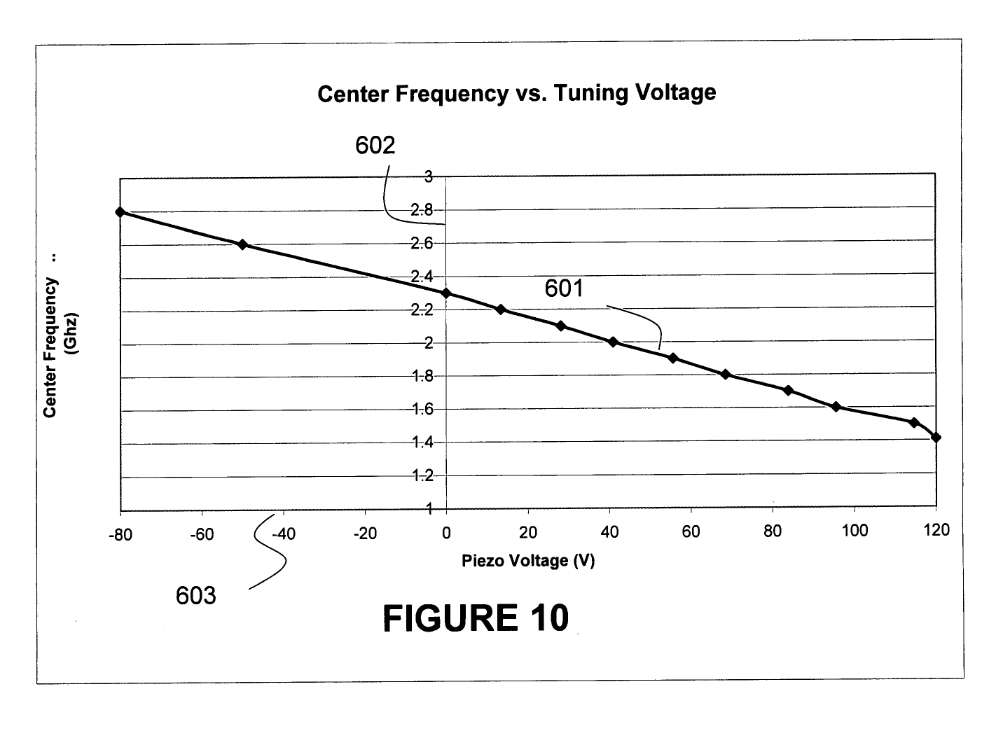

FIG. 10 shows the dependence of the resonator center frequency on the tuning voltage applied to the piezoelectric bimorph actuator. Curve 601 represents the center frequency of the exemplary resonator as a function of the tuning voltage applied to the piezoelectric bimorph.

The center frequency, in Ghz, is shown along axis 602, and the applied piezo voltage, in Volts, is shown along axis 603.

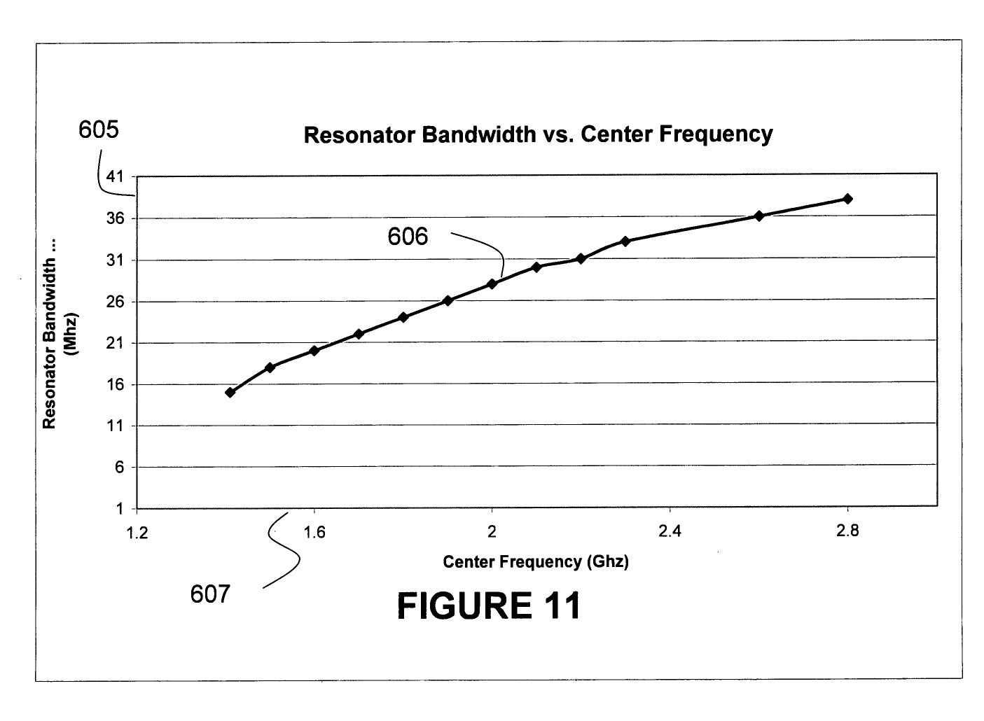

FIG. 11 shows the dependence of the measured resonator bandwidth on the resonator center frequency. The curve 606 shows the variation of resonator bandwidth between 15 Mhz at 1.41 Ghz to 38 Mhz at 2.80 Ghz center frequency. Axis 605 gives the resonator bandwidth in Mhz. Axis 606 gives the resonator center frequency in Ghz.

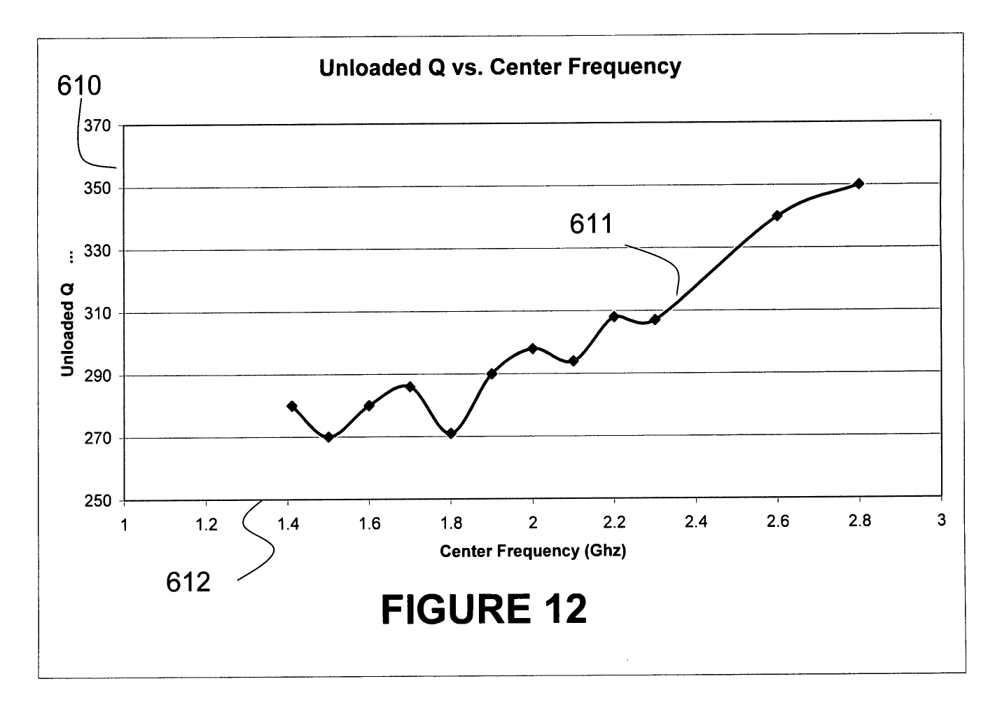

FIG. 12 shows the variation of the resonator unloaded Q with center frequency. Curve 611 represents the unloaded Q as a function of the resonator center frequency. Axis 610 shows the unloaded Q, a dimensionless number, which varies from 270 to 350. Axis 612 shows the center frequency of the resonator which in this case varies from 1.41 Ghz to 2.80 Ghz, as a function of the applied tuning voltage. The unloaded Q is readily calculated from the measured loaded Q and the insertion loss (IL) using the following relation:

$$\begin{matrix}{Q}_{u} = \frac{{Q}_{l} \cdot {10}^{IL / 20}}{{10}^{IL / 20} - 1} , \\ where & ( 10 ) \\ {Q}_{l} = \frac{{f}_{0}}{BW} & ( 11 )\end{matrix}$$

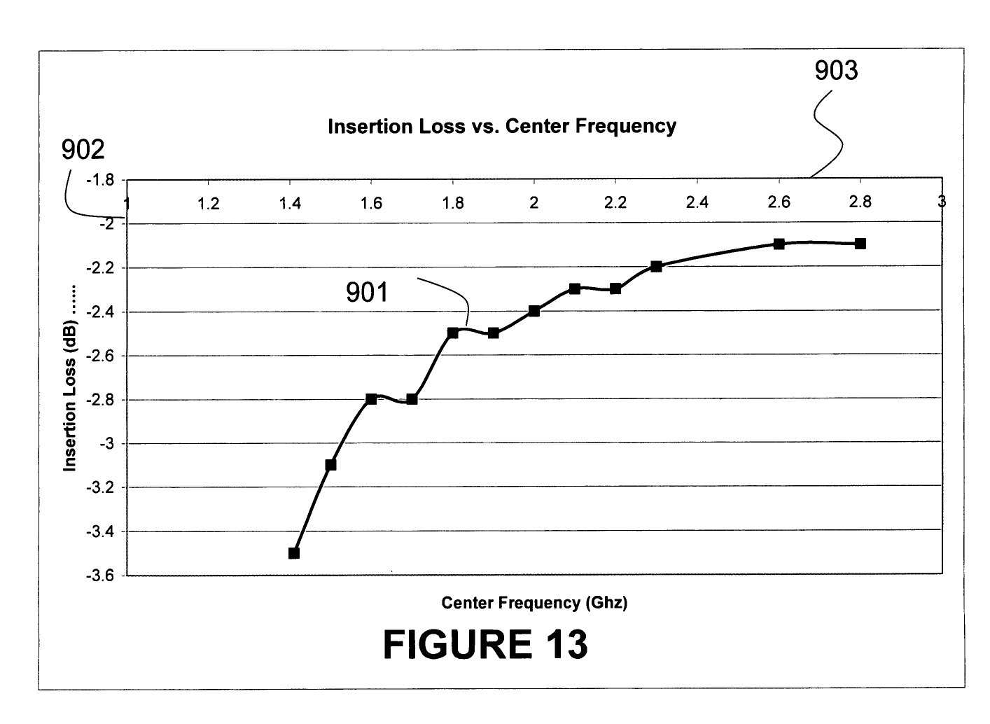

FIG. 13 shows the variation of resonator insertion loss with center frequency. Axis 903 shows the center frequency of the resonator which was tuned between 1.41 Ghz and 2.80 Ghz. Axis 902 shows the measured insertion loss in dB. Curve 901 represents the insertion loss as a function of resonator center frequency, which in this case varies from −3.5 dB at 1.41 Ghz to −2.1 dB at 2.80 Ghz.

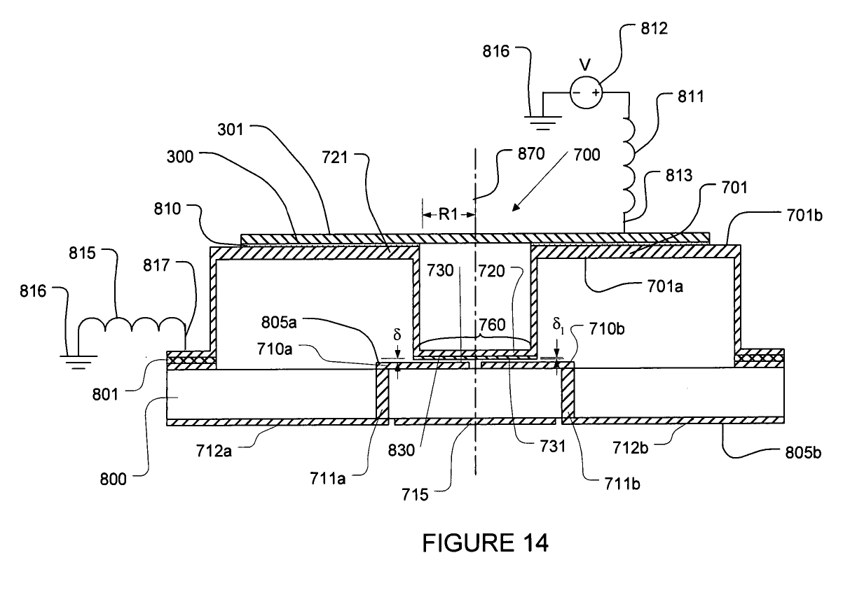

FIG. 14 shows a cross-section of an embodiment of an inventive four-port tunable capacitor based on a modification of the tunable resonator structure disclosed above. An exemplary circuit component 700, includes a first (or upper) structure 701, provided from an elastically deformable material. In one particular embodiment, the circuit component 700 is symmetrical about the axis 870. In another embodiment, the circuit component 700 may be provided having circular symmetry about the axis 870, and thus the circuit component 700 may be substantially round. In yet another embodiment, the structure could be formed in the shape of a polygon or other shape. The first structure 701 may be fabricated from a conductive metal. The first structure 701 may have a thin layer of conductive adhesive 810 disposed upon the surface 701b, which bonds the thin piezoelectric disc 300 to the deformable material 721 creating a piezoelectric bending bimorph actuator. The second layer 800 has a top surface 805a and a bottom surface 805b. A conductive layer disposed upon the top surface 805a may be patterned to form independent variable input and output capacitors, formed between the surfaces 730 of conductive plates 710a and 710b, and the surface 830. In one implementation, a dielectric layer 731, for example parylene-N, may be disposed upon the inner surface of the element 701, preventing conductive surfaces 730 and 830 from touching.

To electrically isolate the variable capacitor from the actuation circuitry, an RF choke 815 may be connected between the conductive structure 701 and the ground 816, with a wire 817. Likewise, an RF choke 811 may be connected with a wire 813 to the top surface 301 of the piezoelectric element 300. The RF choke 811 may be connected to the variable voltage supply 812, which provides a control voltage to the piezoelectric bimorph actuator, thus varying the gap 6, in a manner similar to that employed in the tunable resonator device described earlier.

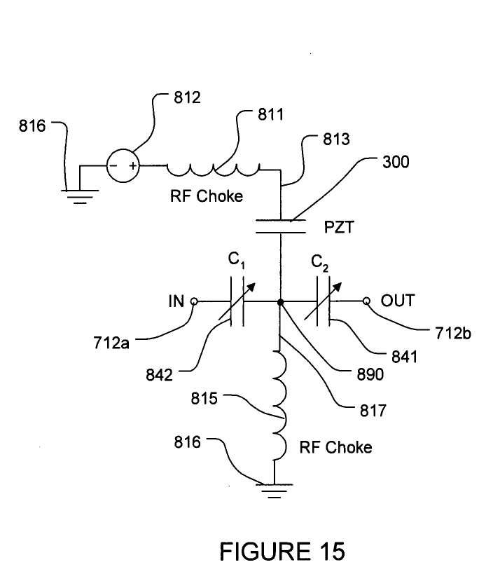

FIG. 15 shows an equivalent circuit model for the exemplary four-port tunable capacitor disclosed in FIG. 14. The variable capacitors 842 and 841 are connected by striplines 712a and 712b. The node 890 is a common terminal for the piezoelectric actuator 300 and the variable capacitors 842 and 841. At RF frequencies, for example frequencies above 50 Mhz, the RF choke inductors 811 and 815 have a high impedance and thus may be modeled as an “open circuit.” Thus at high RF frequencies, the voltage on the node 890 may not be fixed to the ground 816. Conversely, at audio frequencies, for example the typical 0-30 kHz actuation frequency of the piezoelectric bimorph 300, the RF choke may be modeled as a short circuit, and the node 890 may be held at ground. Thus, the high-frequency variable capacitor circuit path and the low-frequency actuator circuit path may be isolated from each other.

The variable capacitors 841 and 842 are electrically connected in series, thus their equivalent capacitance is:

$${C}_{eq} = \frac{{C}_{1} {C}_{2}}{{C}_{1} + {C}_{2}} . \qquad ( 12 )$$

All references cited herein are hereby incorporated herein by reference in their entirety.

Having described preferred embodiments of the invention, it will now become apparent to one of ordinary skill in the art that other embodiments incorporating their concepts may be used. It is felt therefore that these embodiments should not be limited to disclosed embodiments, but rather should be limited only by the spirit and scope of the appended claims.

What is claimed is:

1. A circuit component comprising:
a first structure having first and second opposing surfaces and provided from an elastically deformable material;
a second structure having first and second opposing surfaces, with at least a portion of the first surface of said first structure disposed proximate at least a portion of the first surface of said second structure;
a support structure disposed between the first surface of said first structure and the first surface of said second structure supporting said first surface of said first structure relative to the first surface of said second structure such that the first structure may be elastically deformed, causing at least a portion of the first surface of said first structure to move relative to the first surface of said second structure;
a conductor disposed on the first surface of said first structure in a first conductive region;
a conductor disposed on the first surface of said second structure in a second conductive region; and
a conductor disposed on the first surface of said second structure in a third conductive region, wherein the first conductive region is separated from the second and third conductive regions by a gap, forming a first capacitor comprising the first and second conductive regions, and a second capacitor comprising the first and third conductive regions.

2. The circuit component according to claim 1, further comprising:
a conductor disposed on the first surface of said second structure in a fourth conductive region, wherein the first conductive region is separated from the second, third and fourth conductive regions by a gap, forming a first capacitor comprising the first and second conductive regions, a second capacitor comprising the first and third conductive regions, and a third capacitor comprising the first and fourth conductive regions.

3. The circuit component according to claim 2, further comprising:
a first stripline circuit pattern disposed on the second structure electrically connected to the third conductive region, to form a variable input coupling capacitor; and
a second stripline circuit pattern disposed on the second structure electrically connected to the fourth conductive region to form a variable output coupling capacitor.

4. The circuit component according to claim 1, further comprising:
a conductor disposed on the first surface of said first structure in a fourth conductive region electrically connected to the first conductive region; and
a conductor disposed on the first surface of said second structure in a fifth conductive region electrically connected to the second conductive region, wherein the fourth and fifth conductive regions form an inductor in parallel with the first capacitor.

5. The circuit component according to claim 1, wherein the first and second capacitors have first and second capacitances, and wherein said first capacitance varies in proportion to variations of the gap formed between the first and second conductive regions in response to elastic deformation of the first structure, and the second capacitance varies in proportion to variations of the gap formed between the first and third conductive regions in response to elastic deformation of the first structure.

6. A circuit component comprising:
a first structure having first and second opposing surfaces and provided from an elastically deformable material, wherein said first structure is centered about a central axis oriented substantially perpendicular to the major dimension of the first structure;
a second structure having first and second opposing surfaces, with at least a portion of the first surface of said first structure disposed proximate at least a portion of the first surface of said second structure;
a support structure disposed between the first surface of said first structure and the first surface of said second structure supporting said first surface of said first structure relative to the first surface of said second structure, wherein said support structure is located distal to the central axis of the first structure relative to the first surface of the first structure, such that the first structure may be elastically deformed, causing at least a portion of the first surface of said first structure to move relative to the first surface of said second structure;
a conductor disposed on the first surface of said first structure in a first conductive region; and
a conductor disposed on the first surface of said second structure in a second conductive region, wherein the first conductive region is separated from the second conductive region by a gap, forming a capacitor.

7. The circuit component according to claim 6, further comprising:
a piezoelectric bimorph actuator element attached to at least a portion of the second surface of the first structure, wherein said portion of the second surface is located proximal to the central axis of the first structure, relative to the support structure, such that the piezoelectric bimorph actuator element is operable to elastically deform the first structure in response to a voltage applied thereto.

8. The circuit component according to claim 6, wherein the capacitor has a capacitance, and wherein said capacitance varies in proportion to variations of the gap formed between the first and second conductive regions in response to elastic deformation of at least a portion of the first structure.

9. The circuit component according to claim 6, further comprising:
a conductor disposed on the first surface of said first structure in a third conductive region electrically connected to the first conductive region; and
a conductor disposed on the first surface of said second structure in a fourth conductive region electrically connected to the second conductive region, wherein the third and fourth conductive regions form an inductor in parallel with the first capacitor.

10. The circuit component according to claim 6, further comprising:
a conductor disposed on the first surface of said second structure in a third conductive region, wherein the first conductive region is separated from the second and third conductive regions by a gap, forming a first capacitor comprising the first and second conductive regions, and a second capacitor comprising the first and third conductive regions.

11. The circuit component according to claim 10, further comprising:
a conductor disposed on the first surface of said first structure in a fourth conductive region electrically connected to the first conductive region; and
a conductor disposed on the first surface of said second structure in a fifth conductive region electrically connected to the second conductive region, wherein the fourth and fifth conductive regions form an inductor in parallel with the first capacitor.

12. The circuit component according to claim 10, wherein the first and second capacitors have first and second capacitances, and wherein said first capacitance varies in proportion to variations of the gap formed between the first and second conductive regions in response to elastic deformation of the first structure, and the second capacitance varies in proportion to variations of the gap formed between the first and third conductive regions in response to elastic deformation of the first structure.

13. A method for manufacturing a variable capacitance circuit component comprising the steps of:
forming an elastically deformable first structure having first and second opposing surfaces using a metal electroforming process, said process comprising the steps of:
electroplating one or more thin layers of conductive metal onto a mandrel having a complimentary shape;
polishing the surface of the electroplated conductive metal layer;
dicing the electroplated conductive metal to form an individual elastically deformable first structure; and
releasing the elastically deformable first structure from the mandrel;
forming a second structure having first and second opposing surfaces using a circuit topography patterning process to create a conductor disposed in at least one conductive region on the first surface of said second structure; and
joining said first surface of the elastically deformable first structure to said first surface of the second structure to form the variable capacitance circuit component.

14. The method according to claim 13 wherein said joining step utilizes a joining process selected from the group comprising bonding with conductive adhesive, ultrasonic welding and thermocompression bonding.

15. The method according to claim 13 additionally comprising the step of:
attaching a piezoelectric bimorph element to at least a portion of the second surface of the elastically deformable first structure.

16. The method according to claim 13 wherein the step of forming an elastically deformable first structure having first and second opposing surfaces using a metal electroforming process comprises the steps of:
attaching a piezoelectric bimorph onto a mandrel having a complementary shape;
electroplating one or more thin layers of conductive metal onto the mandrel;
polishing the surface of the electroplated conductive metal layer;
dicing the electroplated conductive metal and piezoelectric bimorph to form an individual elastically deformable first structure including an intimately joined piezoelectric bimorph; and
releasing the elastically deformable first structure from the mandrel.
